(19) United States
(12) Patent Application Publication
(10) Pub. No.: US 2006/0163739 A1
(43) Pub. Date: Jul. 27, 2006

(54) Semiconductor device and method for production thereof

(76) Inventors: Naoki Komai, Kanagawa (JP); Ryuichi Kanamura, Tokyo (JP); Yutaka Ooka, Kanagawa (JP)

Correspondence Address: ROBERT J. DEPKE;LEWIS T. STEADMAN, TREXLER, BUSHNELL, GLANGLORGI, BLACKSTONE & MARR, 105 WEST ADAMS STREET, SUITE 3600, CHICAGO, IL, 60603-6299, US

(21) Appl. No.: 11/321,850

(22) Filed: Dec. 29, 2005

(30) Foreign Application Priority Data
Jan. 26, 2005 (JP) 2005-018367

(51) Int. Cl. H01L 21/44; H01L 23/48; H01L 23/52

(52) U.S. Cl. 257/762; 438/687

(57) ABSTRACT

Disclosed herein is a semiconductor device with improved electromigration durability and a method for producing the semiconductor device. A semiconductor device includes: an interlayer insulating film formed on a first metal wiring; a second metal wiring formed by embedding in the interlayer insulating film; a metal contact formed by embedding in the interlayer insulating film, for connecting between the first metal wiring and the second metal wiring; a first capping layer formed between the first metal wiring and the metal contact; and a barrier metal layer formed between the second metal wiring and the interlayer insulating film, for preventing metal diffusion in the second metal wiring. A method of producing a semiconductor device includes the steps of: forming an interlayer insulating film on a substrate having a first metal wiring formed thereon; forming in the interlayer insulating film a via hole reaching the first metal wiring; selectively forming a first capping layer only on the bottom of the via hole; forming a barrier metal layer on the inner wall of the via hole; and embedding a metal layer in the via hole.

### CROSS REFERENCES TO RELATED APPLICATIONS

The present invention contains subject matter related to Japanese Patent Application JP 2005-018367 filed in the Japanese Patent Office on Jan. 26, 2005, the entire contents of which being incorporated herein by reference.

### BACKGROUND OF THE INVENTION

The present invention relates to a semiconductor device and a method for producing a semiconductor device, and more particularly, to a semiconductor device and a method for production thereof, which involve the groove wiring technology such as dual damascene or single damascene.

The wiring material for LSI is being changed from aluminum alloy into copper because the latter has better electromigration durability and lower resistance than the former. Since copper usually encounters difficulties in dry etching, the copper wiring is formed by previously forming a wiring groove in the interlayer insulating layer and then filling the groove with the wiring material and finally removing the excess part of the wiring material by CMP (Chemical Mechanical Polishing).

Incidentally, it is known that the copper wiring exhibits improved electromigration durability when it is covered with a capping layer of CoWP. (See Non-patent Document 1: T. Ishigami et al., “High Reliability Cu Interconnection Utilizing a Low Contamination CoWP Capping Layer”, IITC (International Interconnect Technology Conference), proceeding, p. 75-77 (2004))

In the case of multi-layer interconnection, it is necessary to make via holes in the interlayer insulating layer for connection between the upper wiring and the lower wiring. The step of making via holes needs etching through a resist film on the interlayer insulating film, removal of resist by ashing, and wet cleaning to remove etching residues.

### SUMMARY OF THE INVENTION

The disadvantage of the above-mentioned conventional technology is that the capping layer formed on the low level wiring is partly or entirely lost from the via holes after etching, ashing, and wet etching. This makes the wiring vulnerable to electromigration that occurs when electrons flow from the upper level to the lower level.

The present invention was completed in view of the foregoing. It is an object of the present invention to provide a semiconductor device with improved electron migration durability and a method for production thereof.

The semiconductor device according to the present invention includes an interlayer insulating film formed on a first metal wiring, a second metal wiring embedded in said interlayer insulating film, a metal contact embedded in said interlayer insulating film for connection between said first metal wiring and said second metal wiring, a first capping layer formed between said first metal wiring and said metal contact for the prevention of electromigration in the metal wiring, and a barrier metal layer formed between said second metal wiring and said interlayer insulating film for the prevention of metal diffusion in said second metal wiring.

The semiconductor device according to the present invention has the first capping layer which is formed between the first metal layer and the metal contact for the prevention of electromigration in the metal wire. Thus the first capping layer reinforces the region immediately under the contact from which electromigration starts when electrons flow from the second metal wiring in the upper level to the first metal wiring in the lower level.

The method of producing the semiconductor device according to the present invention includes a step of forming an interlayer insulating film on a substrate having a first metal wiring formed thereon, a step of forming in said interlayer insulating film a via hole reaching said first metal wiring, a step of selectively forming a first capping layer only on the bottom of said via hole, a step of forming a barrier metal layer on the inner wall of said via hole, and a step of embedding a metal layer in said via hole.

The method of producing the semiconductor device according to the present invention has the step of selectively forming the first capping layer only on the bottom of the via hole after a via hole reaching the first metal wiring has been formed. Thus the first capping layer reinforces the region immediately under the contact at which electromigration starts when electrons flow from the second metal wiring in the upper level to the first metal wiring in the lower level.

The semiconductor device according to the present invention has improved electromigration durability. The method of producing the semiconductor device according to the present invention provides a semiconductor device having improved electromigration durability.

### BRIEF DESCRIPTION OF THE DRAWINGS

FIG. 1 is a sectional view showing one example of the semiconductor device pertaining to the present invention;

FIGS. 2A and 2B are sectional views showing the process of fabricating the semiconductor device pertaining to the present invention;

FIGS. 3A and 3B are sectional views showing the process of fabricating the semiconductor device pertaining to the present invention;

FIGS. 4A and 4B are sectional views showing the process of fabricating the semiconductor device pertaining to the present invention;

FIGS. 5A and 5B are sectional views showing the process of fabricating the semiconductor device pertaining to the present invention;

FIGS. 6A and 6B are sectional views showing the process of fabricating the semiconductor device pertaining to the present invention;

FIGS. 7A and 7B are sectional views showing the process of fabricating the semiconductor device pertaining to the present invention;

FIGS. 8A and 8B are sectional views showing the process of fabricating the semiconductor device pertaining to the present invention;

FIG. 9 is a sectional view showing the process of fabricating the semiconductor device pertaining to the present invention;

FIG. 10 is a sectional view showing another example of the semiconductor device pertaining to the present invention;

FIG. 11 is a sectional view showing another example of the semiconductor device pertaining to the present invention;

FIG. 12 is a sectional view showing another example of the semiconductor device pertaining to the present invention;

FIG. 13 is a sectional view showing another example of the semiconductor device pertaining to the present invention; and

FIG. 14 is a sectional view showing another example of the semiconductor device pertaining to the present invention.

### DETAILED DESCRIPTION OF THE PREFERRED EMBODIMENTS

The embodiments of the present invention will be described with reference to the accompanying drawings.

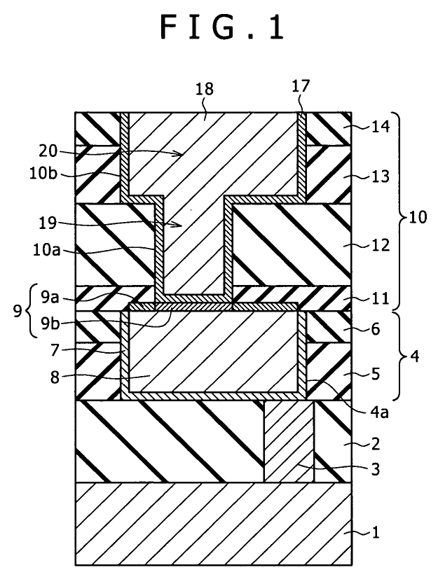

FIG. 1 is a sectional view showing one example of the semiconductor device pertaining to the present invention.

There is shown a substrate 1 of semiconductor such as silicon. On the substrate 1 is an interlayer insulating film of silicon oxide. In the interlayer insulating film 2 is a contact 3 of tungsten. On the substrate 1 are transistors and other semiconductor elements to which the contact 3 is connected.

On the interlayer insulating film 2 and the contact 3 is an interlayer insulating film 4. In this embodiment, the interlayer insulating film 4 is composed of an organic insulating film 5 of polyarylene and a hard mask 6 of silicon oxide which has been used to form the insulating film 5. Incidentally, the insulating film 5 may also be formed from SiCOH or may be replaced by so-called Low-k film.

In the interlayer insulating film 4 is a wiring groove 4a. In the wiring groove 4a is a first metal wiring 8 of copper, with a barrier metal layer 7 interposed between the metal wiring 8 and the inner wall of the wiring groove 4a. The barrier metal layer 7 is formed between the first metal wiring 8 and the interlayer insulating film 4 in order to prevent the diffusion of copper in the case where the first metal wiring 8 is made of copper, because copper diffuses readily and rapidly into the surrounding insulating material. The barrier metal layer 7 may be a single layer of tantalum (Ta) or may be composed of layers of tantalum nitride (TaN) and tantalum (Ta).

On the first metal wiring 8 is a capping layer 9 to protect the metal wiring against electromigration. (Electromigration is one kind of diffusion induced by mutual action of metal atoms (copper in this case) in the metal wiring and electrons flowing through the metal wiring. It is the movement of metal ions which is caused by an exchange of momentum between metal ions and electrons carrying electric current. It gives rise to local voids and hillocks.) The capping layer 9 on the first metal wiring 8 prevents the movement of metal ions.

The capping layer 9 is composed of a first capping layer 9b and a second capping layer 9a. The former is formed on the top of the first metal wiring 8 in the via hole 10a, and the latter is formed on the top of the first metal wiring 8, except for the region in the via hole 10a. The capping layer 9 is made of CoWP (cobalt-tungsten alloy containing phosphorus), for example. The capping layer 9 may also be made of other alloys than CoWP, such as CoWB (cobalt-tungsten alloy containing boron), NiWP (nickel-tungsten alloy containing phosphorus, and NiWB (nickel-tungsten alloy containing boron).

On the capping layer 9 and the interlayer insulating film 4 is the interlayer insulating film 10, which is composed of an etching stopper layer 11, a first insulating film 12, a second insulating film 13, and a first hard mask 14, which are sequentially deposited upward.

The etching stopper layer 11 is made of silicon carbide (SiC), SiCN, or the like. The first insulating film 12 is made of SiOC or the like. The second insulating film 13 is an organic insulating film made of polyarylene or the like. The first hard mask 14 is made of silicon oxide or the like.

In the etching stopper layer 11 (in the interlayer insulating film 10) and the first insulating film 12 is the via hole 10a. In the second insulating film 13 and the first hard mask 14 is the wiring groove 10b communicating with the via hole 10a.

In the via hole 10a and the wiring groove 10b is the metal layer 18 of copper, with the barrier metal layer 17 placed thereunder which covers the inner wall of the via hole 10a and the wiring groove 10b. The barrier metal layer 17 prevents the diffusion of copper in the metal layer 18. The barrier metal layer 17 may be a single layer of tantalum (Ta) or may be composed of layers of tantalum nitride (TaN) and tantalum (Ta). The metal layer 18 embedded in the via hole 10a constitutes the metal contact 19 and the metal layer 18 embedded in the wiring groove 10b constitutes the second metal wiring 20.

The semiconductor device according to this embodiment has the capping layer 9b which is formed between the contact 19 and the first metal wiring 8. Thus the capping layer 9b reinforces the region immediately under the contact 19 at which electromigration starts when electrons flow from the second metal wiring 20 in the upper level to the first metal wiring 8 in the lower level. This improves the electromigration durability, thereby eliminating voids due to electromigration, and improves the reliability of the wiring.

In addition, the capping layer 9a is also formed on the top of the first metal wiring 8 (outside of the contact 19) for further improvement in electromigration durability.

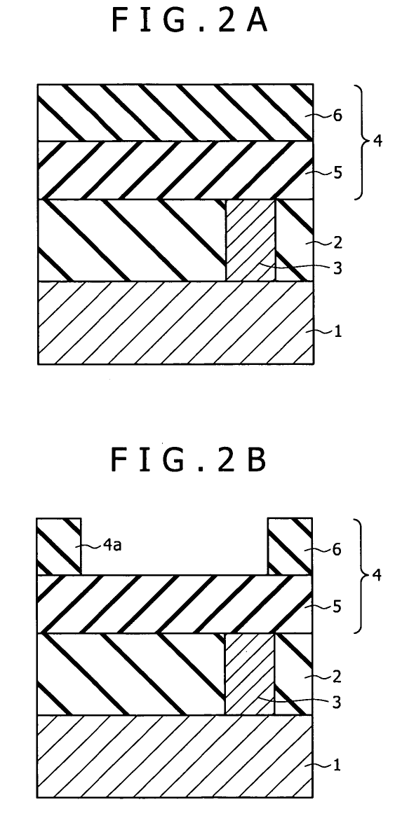

The semiconductor device pertaining to this embodiment is fabricated by the method which is described below with reference to FIGS. 2 to 8.

The initial steps (up to the formation of the first metal wiring 8 and the capping layer 9 in the lower level) will be described first. It is assumed that the first metal wiring 8 is formed by the single damascene process (to form a groove wiring).

As shown in FIG. 2A, the silicon wafer (substrate 1), on which transistors and other semiconductor elements have been formed, is covered with the interlayer insulating film 2 of silicon oxide. In the interlayer insulating film 2 is formed the contact 3 of tungsten for connection to transistors. On the interlayer insulating film 2 and the contact 3 is formed the interlayer insulating film 4 in two steps. First, the insulating film 5 (about 200 nm thick) is formed from polyarylene. Second, the hard mask 6 (about 200 nm thick) on the insulating film 5 is formed from silicon oxide by plasma CVD.

As shown in FIG. 2B, the hard mask 6 undergoes etching through a resist mask so that the pattern of the wiring groove 4a is formed. The organic insulating film 5 has a high etching selective ratio.

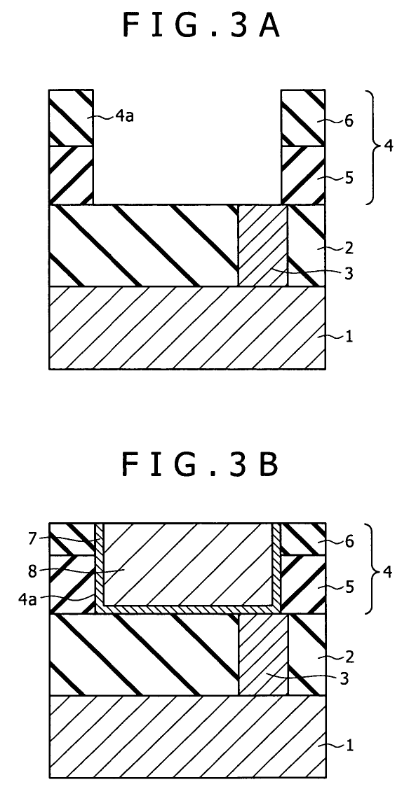

As shown in FIG. 3A, the insulating film 5 undergoes etching through the hard mask 6 as an etching mask. Thus the wiring groove 4a is formed in the interlayer insulating film 4. When the insulating film 5 undergoes etching, the resist mask on the hard mask 6 also undergoes etching and hence it disappears.

As shown in FIG. 3B, in the wiring groove 4a of the interlayer insulating film 4 are formed the barrier metal layer 7 and the first metal wiring 8. This step proceeds as follows. First, a Ta barrier metal layer (10 nm) and a Cu seed layer (80 nm) are formed by PVD (Physical Vapor Deposition). Second, copper is deposited (up to a thickness of 1000 nm) by electroplating process so that copper is embedded in the wiring groove 4a. Unnecessary copper on the interlayer insulating film 4 is removed by CMP process, and unnecessary thallium (as the barrier metal layer 7) is also removed by CMP process. The CMP process also shaves away (100 nm) the hard mask 6 on the insulating film 5. Thus the barrier metal layer 7 of thallium and the first metal wiring 8 of copper are formed in the wiring groove 4a.

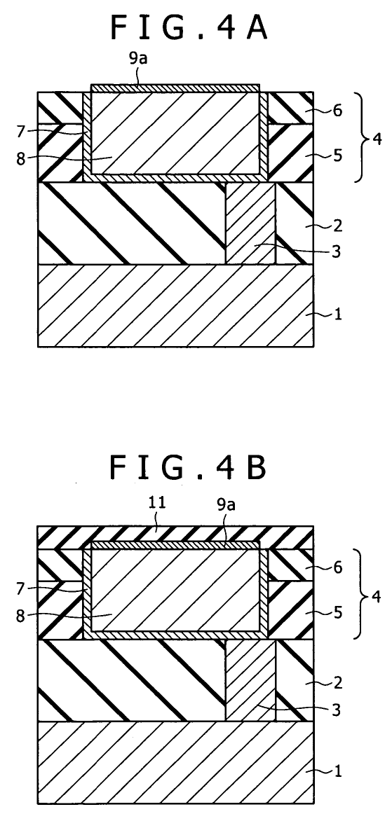

As shown in FIG. 4A, the second capping layer 9a is selectively formed by electroless plating only on the top of the first metal wiring 8. This step proceeds as follows. First, cleaning with an aqueous solution of an organic acid (such as citric acid and oxalic acid) is performed to remove the oxide film on the first metal wiring 8 and the anticorrosive compound for copper which has been formed on the surface of the first metal wiring 8 as the result of CMP process. (The anticorrosive compound is benzotriazole or a derivative thereof contained in the slurry for CMP process.) Second, the wafer is treated with an aqueous solution of palladium sulfate. (This step may be accomplished by dipping the wafer entirely in an aqueous solution of palladium sulfate, dropping an aqueous solution of palladium sulfate onto the wafer, or spraying the wafer with an aqueous solution of palladium sulfate.) This treatment permits the displacement plating of palladium only on the first metal wiring 8 through the chemical reaction represented by Pd²⁺+Cu→Pd+Cu²⁺, which takes place because palladium has a smaller ionization tendency than copper. Then, the wafer is treated with a plating solution of CoWP, so that CoWP film (10 to 20 nm thick) is formed on copper by selective plating which employs palladium as a catalyst. Thus the capping layer 9a of CoWP is formed only on the first metal wiring 9.

The plating of CoWP is carried out under the following conditions. The plating solution is composed of ammonium tungstate 10 g/L, cobalt chloride 30 g/L, ammonium hypophosphite (reducing agent) 20 g/L, ammonium oxalate 80 g/L, and surfactant. Also, the plating solution was kept at 90° C. and pH 8.5 to 10.5.

The reducing agent mentioned above may be replaced by dimethylamineborane (DMAB) in the case where the capping layer 9a is formed from CoWB by electroless plating. Also, the cobalt chloride may be replaced by nickel chloride in the case where NiWP film is formed by electroless plating. Moreover, the cobalt chloride may be replaced by nickel chloride and the reducing agent may be replaced by dimethylamineborane (DMAB) in the case where NiWB film is formed by electroless plating.

As shown in FIG. 4B, on the capping layer 9a and the interlayer insulating film 4 is formed the etching stopper layer 11 of SiCN (50 nm thick) from trimethylsilane and NH₃.

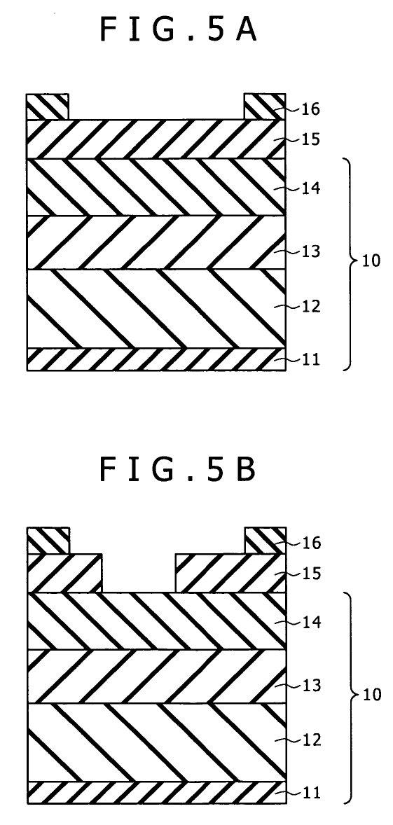

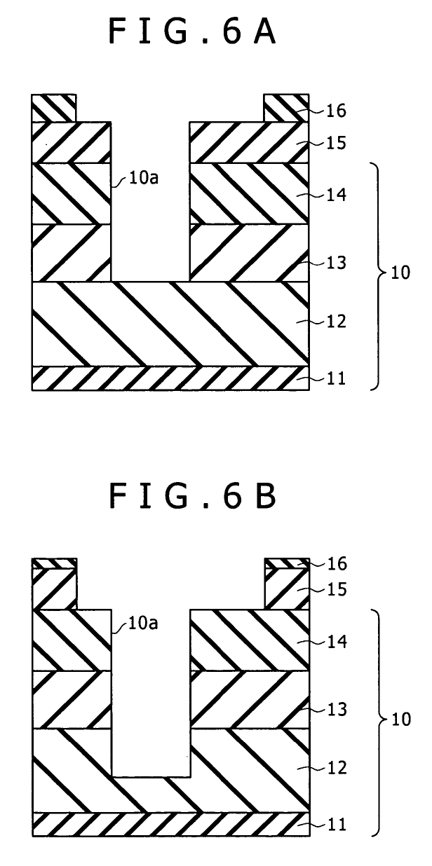

The subsequent steps (up to the formation of the upper level wiring by dual damascene process (to form the groove wiring and contact simultaneously) will be described. Incidentally, FIGS. 5 and 6 show only the upper layer (above the etching stopper layer 11) for the sake of brevity.

As shown in FIG. 5A, the interlayer insulating film 10 is formed in the following manner. First, an SiOC film (200 nm thick) is deposited from trimethylsilane by plasma CVD to form the first insulating film 12. The first insulating film 12 is coated with a polyarylene film (200 nm thick) to form the second insulating film 13. The second insulating film 13 is coated with SiO₂ film (200 nm thick) deposited from SiH₄ (silane) by plasma CVD, to form the first hard mask 14. Thus the formation of the interlayer insulating film 10 is completed. Then, the first hard mask 14 is coated with the second hard mask 15 of SiN by plasma CVD, which is used to fabricate the wiring groove and the via hole. The third hard mask 16 of SiO₂ is formed by plasma CVD. A resist mask (not shown) is formed, and the third hard mask 16 (the uppermost layer) undergoes etching through the resist mask to form the pattern of the wiring groove.

As shown in FIG. 5B, a resist mask is formed again and the second hard mask 15 undergoes etching through the resist mask to form the pattern of the via hole in the second hard mask 15.

As shown in FIG. 6A, the first hard mask 14 undergoes dry etching through the second hard mask 15 as an etching mask, and then the second insulating film 13 undergoes dry etching. Thus the via hole 10a is formed in the first hard mask 14 and the second insulating film 13. At this time, the resist mask which has been used to fabricate the second hard mask 15 undergoes dry etching together with the second insulating film 13 which is organic.

As shown in FIG. 6B, dry etching is performed on the second hard mask 15 through the third hard mask 16 as an etching mask, thereby forming the pattern of the wiring groove in the second hard mask 15. In this step, the first insulating film 12 of SiOC is partly etched, so that the via hole 10a extends to the intermediate depth of the first insulating film 12.

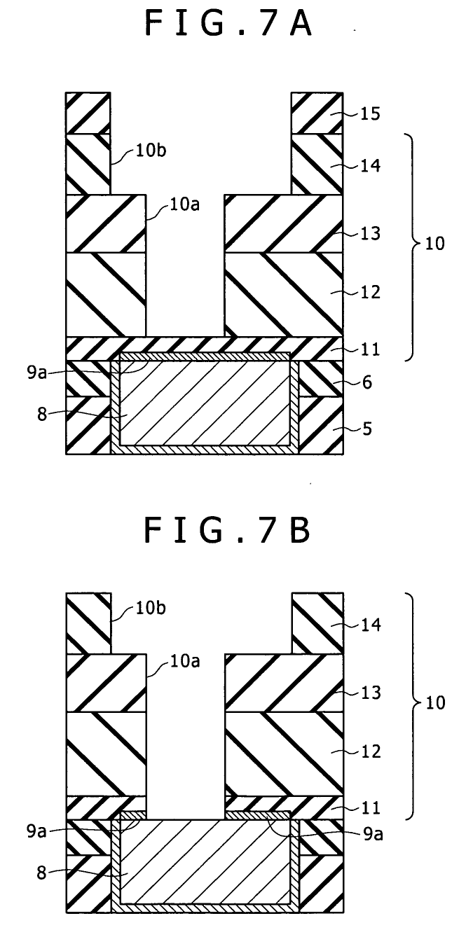

As shown in FIG. 7A, dry etching is performed on the first hard mask 14 through the second hard mask 15 as an etching mask, thereby forming the wiring groove 10b in the first hard mask 14. At this time, the first insulating film 12 also undergoes etching, which forms the via hole 10a reaching the etching stopper layer 11.

As shown in FIG. 7B, dry etching is performed on the etching stopper layer 11 on the first metal wiring 8 together with the second hard mask 15 of SiN which is the uppermost layer. After that, wet cleaning is performed to remove etching residues from the via hole 10a. The dry etching mentioned above causes cobalt in the capping layer 9a to be oxidized by oxygen contained in the dry etching gas. The subsequent wet cleaning removes partly or entirely the capping layer 9a of CoWP in the via hole 10a. Incidentally, FIG. 7B illustrates the intermediate product, with the capping layer 9a in the via hole 10a entirely removed. The foregoing holds true with CoWB, NiWP, and NiWB.

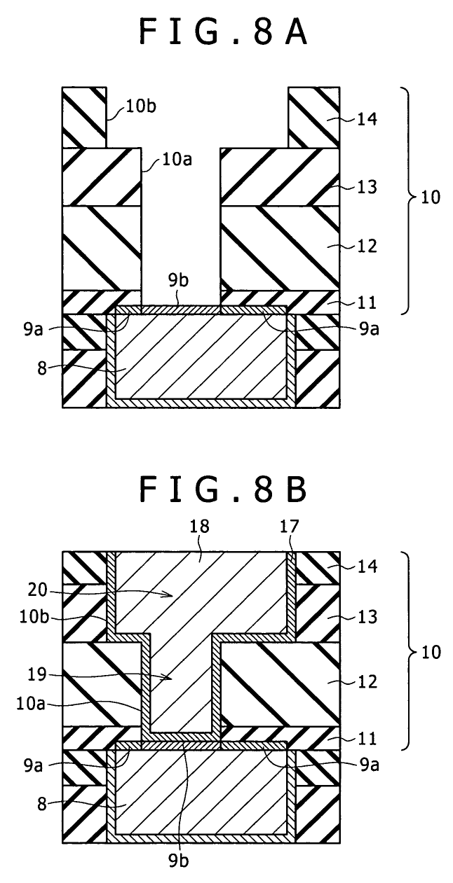

As shown in FIG. 8A, the first capping layer 9b is formed only on that part of the first metal wiring 8 which is exposed at the bottom of the via hole 10a. This step is carried out in the following manner. First, the wafer is treated with an aqueous solution of palladium sulfate, so that displacement plating of Pd is performed only on Cu (or the bottom of the via hole 10a) in the same way as the above-mentioned displacement plating. Incidentally, treatment with palladium may be omitted because there is the possibility that palladium is not removed by wet cleaning. Then, the wafer is treated with a plating solution of CoWP, so that CoWP film (10 to 20 nm thick) is formed on copper by selective plating which employs palladium as a catalyst. In this way the capping layer 9b is formed. Plating is carried out under the same conditions as mentioned above. Also, the capping layer 9b may be any of CoWB film, NiWP film, and NiWB film.

As shown in FIG. 8B, the barrier metal layer 17 is formed on the inner wall of the via hole 10a and the wiring groove 10b, and the via hole 10a and the wiring groove 10b are filled with the metal layer 18. Thus the contact 19 and the second metal wiring 20 are formed. This step is accomplished as follows. First, a tantalum film (10 nm thick) as the barrier metal layer 17 and a copper film (80 nm thick) as the seed layer for plating are formed by PVD. Second, copper is deposited (1000 nm thick) by electroplating so as to fill the via hole 10a and the wiring groove 10b with copper. Finally, unnecessary copper and tantalum which have been deposited on the interlayer insulating film 10 (except for the via hole 10a and the wiring groove 10b) are removed by CMP. This CMP shaves away the first hard mask 14 of silicon oxide as much as about 100 nm.

The desired semiconductor device of multilevel wiring structure is obtained by repeating the steps shown in FIGS. 4 to 8, viz. by repeating the steps of forming the capping layer, forming the interlayer insulating film, forming the wiring groove and via hole in the interlayer insulating film, selectively forming the capping layer on the bottom of the via hole, and embedding the metal layer.

The advantage of the above-mentioned method for fabricating the semiconductor device according to this embodiment is that the capping layer 9a in the via hole 10a may be lost partly or entirely without any problem when the via hole 10a is made, because the capping layer 9b is selectively formed only on the bottom after the via hole 10a and the wiring groove 10b have been formed in the interlayer insulating film 10.

The capping layer 9b which has been selectively formed only on the bottom of the via hole 10a reinforces the region immediately under the contact 19 at which electromigration starts when electrons flow from the second metal wiring 20 in the upper level to the first metal wiring 8 in the lower level. Therefore, the resulting semiconductor device has improved electromigration durability and improved wiring reliability on account of the absence of voids due to electromigration.

The electromigration durability is enhanced by the fact that the capping layer 9a is formed on the top of the first metal wiring 8 outside the contact 19.

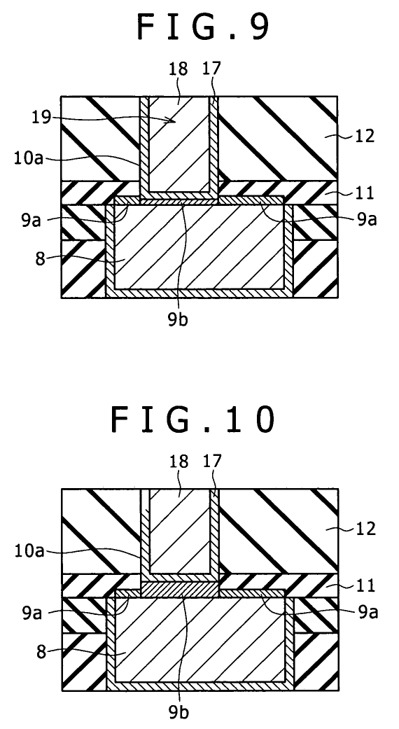

It is not always necessary that the capping layer 9a and the capping layer 9b have the same thickness. That is, the capping layer 9b may be thinner than the capping layer 9a as shown in FIG. 9, or the capping layer 9b may be thicker than the capping layer 9a as shown in FIG. 10. The thickness of the capping layer 9b in the via hole 10a may be about 5 to 20 nm.

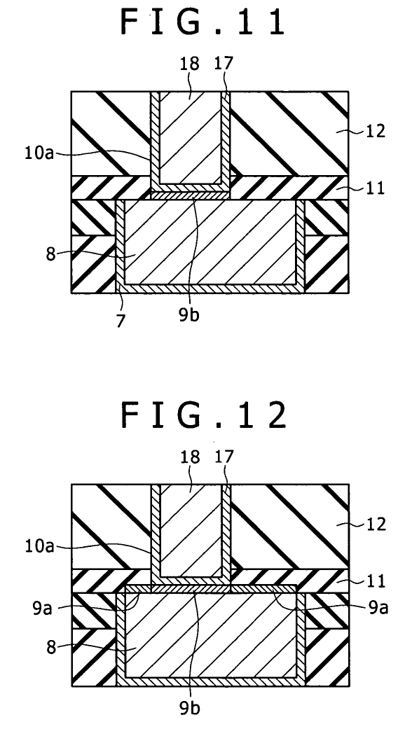

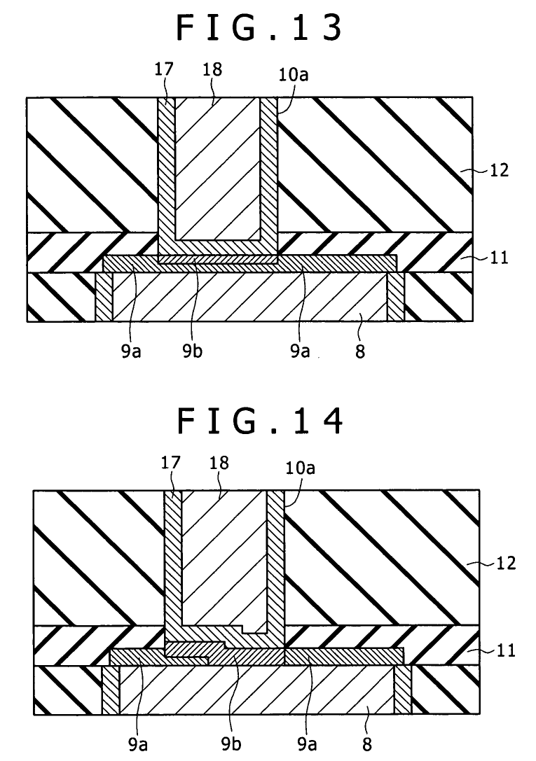

The foregoing structure may be modified such that the capping layer 9a is omitted but only the capping layer 9b is formed on the bottom of the via hole 10a, as shown in FIG. 11. The modified structure shown in FIG. 11 may be obtained by omitting the step of forming the capping layer 9a shown in FIG. 4A.

The structure may also be modified such that the capping layer 9a and the capping layer 9b are made from different materials. For example, the capping layer 9a may be a CuSi film. In this case, it is possible to selectively form a CuSi film on the first metal wiring 8 of Cu in the step of depositing SiCN from silane (SiH₄) gas to form the etching stopper layer 11 of SiCN.

The embodiment illustrated above is characterized in that the capping layer 9a exposed in the via hole 10a is entirely removed when the via hole 10a is formed. However, the present invention may also be applied to the case in which the capping layer 9a in the via hole 10a is thinned as shown in FIG. 14 or the case in which the capping layer 9a in the via hole 10a partly remains as shown in FIG. 14. The advantage of these cases is that the capping layer 9b formed in the via hole 10a has a film thickness necessary to improve electromigration durability as in the embodiment mentioned first.

The foregoing embodiment is not intended to restrict the scope of the present invention. The structure of the interlayer insulating film 10 may be modified, and the composition of the plating solution (CoWP) may be modified, with cobalt chloride replaced by cobalt sulfate.

Various changes and modifications may be made in the invention without departing from the sprit and scope thereof.

What is claimed is:

1. A semiconductor device, comprising
an interlayer insulating film formed on a first metal wiring;
a second metal wiring formed by embedding in said interlayer insulating film;
a metal contact formed by embedding in said interlayer insulating film, for connecting between said first metal wiring and said second metal wiring;
a first capping layer formed between said first metal wiring and said metal contact; and
a barrier metal layer formed between said second metal wiring and said interlayer insulating film, for preventing metal diffusion in said second metal wiring.

2. The semiconductor device as defined in claim 1, further comprising
a second capping layer formed on the top of the first metal wiring excluding the region on which the first capping layer has been formed.

3. The semiconductor device as defined in claim 1, in which the first capping layer and the second capping layer are formed from the same material.

4. A method of producing a semiconductor device, comprising the steps of:
forming an interlayer insulating film on a substrate having a first metal wiring formed thereon;
forming in said interlayer insulating film a via hole reaching said first metal wiring;
selectively forming a first capping layer only on the bottom of said via hole;
forming a barrier metal layer on the inner wall of said via hole; and
embedding a metal layer in said via hole.

5. The method of producing a semiconductor device as defined in claim 4, wherein the step of forming the first capping layer is carried out in such a way that the capping layer is selectively formed by electroless plating only on the first metal wiring which is exposed at the bottom of the via hole.

6. The method of producing a semiconductor device as defined in claim 4, wherein
the step of forming the via hole is carried out in such a way that the via hole reaching the first metal wiring and the wiring groove communicating with the via hole are formed in the interlayer insulating film,
the step of forming the barrier metal layer is carried in such a way that the barrier metal layer is formed on the inner wall of the via hole and the wiring groove, and
the step of embedding the metal layer is carried out in such a way that the metal layer is embedded in the via hole and the wiring groove.

7. The method of producing a semiconductor device as defined in claim 4, further comprising a step of selectively forming the second capping layer only on the top of the first metal wiring prior to the step of forming the interlayer insulating film.
